(19) United States
(12) Patent Application Publication
(10) Pub. No.: US 2002/0168001 A1
(43) Pub. Date: Nov. 14, 2002

(54) Systems and method for determining the phase angle response in a CATV system

(76) Inventor: Jeffrey Ramsey, Indianapolis, IN (US)

Correspondence Address: Harold C. Moore, Maginot, Addison & Moore, Bank One Center/Tower, 111 Monument Circle, Suite 3000, Indianapolis, IN, 46204-5115, US

(21) Appl. No.: 09/851,892

(22) Filed: May 9, 2001

(51) Int. Cl. H03H 7/30

(52) U.S. Cl. 375/232

(57) ABSTRACT

A system and method determines a group delay of a channel in a CATV system. The system and method obtain a set of equalizer coefficients from an equalizer, the set of equalizer coefficients representative of a measure of a response of the channel. The system and method also generate a phase response of the channel based upon the set of equalizer coefficients. Thereafter, the group delay for the channel is generated based upon the generated phase response.

### FIELD OF THE INVENTION

The present invention relates generally to analyzing transmission characteristics of an RF communication network, and more particularly, to determining group delay of a CATV communication network.

### BACKGROUND OF THE INVENTION

In broad terms, a radio frequency (“RF”) communication network supports transmission of information signals from a source location to a destination location through (or “over” or “on”) an RF communication channel. Depending on the application, the information signals may be analog or digital in nature. Digital signals tend to afford significant advantages relative to analog techniques, such as, for example, improved noise immunity and facilities for encryption, which can provide enhanced communication reliability and security, respectively. Analog and digital transmissions propagate an information signal through a communication medium by converting the information signal into a form suitable for effective transmission over the medium.

The propagation medium of an RF communication network may support the simultaneous transmission of more than one information signal by dividing the frequency spectrum of the propagation medium into discrete bandwidth groupings called channels and providing a carrier wave for each channel. The information signal is usually used to vary a parameter of the carrier wave for a channel so the frequency spectrum of the modulated carrier is confined within the bandwidth of one of the channels defined for a propagation medium.

A receiver at a destination location receives the modulated carrier waves for the channels to which the receiver is tuned. The receiver may then recover a version of the original information signal from the modulated carrier received from the corresponding channel of the propagation medium. The recovery process includes demodulation of the received signal in a manner that is generally the inverse of the modulation performed by the source transmitter.

A cable television (“CATV”) network is one type of RF communication network. CATV networks have grown in importance and use for transmitting television and other information signals to various analog and/or digital devices such as analog television sets and/or personal computers, respectively, and, lately, for a growing number of digital television sets. Originally, CATV networks were used in locations that could not directly receive over-the-air television transmissions because of large distances between transmitters and receivers or because of interfering buildings or terrain. The propagation medium for such systems is coaxial cable because it shields signals carried by the cable from electromagnetic and radio frequency interference better than air. By contrast, RF communication networks that transmit signals principally through the earth's atmosphere (such as traditional radio and television networks) are prone to noise interference and require a “line of sight” communication path.

In recent years, cable transmissions have become popular even in areas where receptions of over-the-air television broadcasts are satisfactory. In these areas, the wide bandwidth of CATV networks has been increasingly exploited to provide additional channels and new services that have not been available from traditional television networks, such as bi-directional data communication and videotext. Bi-directional communication may be implemented on a single coaxial cable by dividing the available frequency spectrum of a channel on the cable into two sub-channels. The forward sub-channel carries signals in the forward or downstream (away from the head end) direction and the return sub-channel carries signals in the reverse or upstream (toward the head end) direction. A customer device attached to the network receives signals from the head end on a forward sub-channel and transmits signals to the head end on a return sub-channel.

A typical CATV system includes a head end where information signals are originated for transmission to subscribers over a distribution network. The distribution network includes coaxial cable and may also include optical fiber. Individual subscriber sites are coupled to the coaxial cable of the distribution network through taps. Also, disbursed throughout the network are distribution sites where amplifiers are located. These amplifiers may include filters that are used to remove distortions in the signals and then the filtered signal is amplified to ensure an adequate signal-to-noise ratio (SNR) of the signal is maintained during its propagation through the system to the next distribution site or tap. As the number of customers and the development of new services grow, the electrical loads on the distribution network increase and the communication operations of a CATV system becomes increasingly complex. CATV system not only require verification testing during construction and/or expansion to confirm that the distribution network can reliably carry signals but further periodic testing is required to ensure the transmission design characteristics of the distribution network remain stable. Additionally, complex RF communication systems, such as CATV systems, suffer occasional problems and failures from component failure or fatigue. When such problems arise, the component causing the problem must be located so that it may be repaired or replaced.

One method used for verifying reliable operation of a CATV distribution network and other RF communication networks is by testing the quality of signals received at various locations in the network. Heretofore, this has been accomplished by using a head end test unit to inject a reference signal into the network portion under test and measuring (relative to the reference signal) the magnitude and phase of the signal received at one or more remote locations on the network. A remote test unit located at a distribution site or subscriber tap on the network typically measures the demodulated signal received at the site. To thoroughly test a channel, the reference signal is injected into each frequency of the bandwidth across a channel supported by the network.

Such testing has historically been accomplished by “sweeping” the frequencies of each channel supported by the network with the reference signal and measuring the magnitude and phase of each signal received at the remote location. The testing process typically required the head end to send a telemetry signal to the remote test unit followed by the frequency sweep reference signals. The telemetry signal synchronized the remote test unit to the head end test unit for the frequency sweep. At the end of the sweep, the head end test unit again transmitted telemetry signals to the remote test unit for another frequency sweep. In addition to synchronizing the remote test unit to the head end test unit for a sweep, the telemetry signals also identify the frequencies to be swept and the power level (magnitude) of the reference signal to be injected. The remote test unit uses this information and its own measurements to determine the frequency response characteristics of the network at the site of the remote test unit. The remote test unit may then display the frequency response data.

One problem with frequency sweep testing techniques is the disruption of subscriber service. When the sweep is being performed, the reference signal being injected by the head end test unit interferes with the subscriber's reception of a channel as it is swept. Although this interruption is brief, it is noticeable. Because a frequency sweep test is usually conducted more than once, the disruption occurs several times.

To address this problem, techniques for obtaining data without significantly disrupting service have been developed. For example, U.S. Pat. No. 5,751,766 to Kletsky et al. (“Kletsky”) shows a method and apparatus for non-invasively testing the performance of a digital communication system. One embodiment is used to diagnose digital television cable broadcast systems. The test system uses the filter parameters of an adaptive equalizer of a digital receiver to correct for communication channel imperfections. The pseudoinverse of the transfer function of this adaptive equalizer is then used to compute the amplitude-frequency response of the components of the propagation path of the signal up to the input of the adaptive equalizer. In Kletsky, the pseudoinverse of the equalizer transfer function may either be determined from the weights of the adaptive equalizer or from the weights of a second adaptive equalizer that converges to the demodulated signal received from the channel.

However, the previously known “in-service” systems do not compute a phase response from the weights of an adaptive equalizer. Yet, with the increasing use of complex modulation schemes (such as QPSK and increasing orders of QAM), effective characterization and maintenance of the phase responses of CATV networks are becoming increasingly important.

Accordingly, there is a need for a technique for obtaining a phase response at a single site in a CATV system or between two sites in a CATV network without significantly disrupting communication through the network or at one or more sites. In particular, there is a need for measuring the group delay of a demodulated signal. Group delay indicates the delay imparted to the signal by the network components and cable between a head end transmitter and the demodulation components of a receiver. Because group delay is derived from the phase response, there is a need to obtain and measure the phase response of the portion of the CATV network that presents the demodulated signal to a receiver.

### SUMMARY OF THE INVENTION

The limitations of the previously known CATV network testing devices are overcome by a system implementing the method of the present invention. The system includes a summer for receiving a demodulated signal from a CATV network, an adaptive equalizer for performing a transfer function on a demodulated signal, a weight update device for adjusting the coefficients of the adaptive equalizer based on an error signal, and a processor for generating the group delay for the channel from the phase angles using the coefficients of the adaptive equalizer.

In particular, in one embodiment, the adaptive equalizer is operably coupled to receive a demodulated digital signal and is operable to generate an equalized signal using a set of equalizer coefficients. The weight update device is operable to generate the set of equalizer coefficients using an error signal, the error signal representative of a difference between an ideal demodulated signal and the received demodulated signal. The processor is operably coupled to receive said set of equalizer coefficients from the weight update device, and is operable to generate a phase response of the channel based upon the set of equalizer coefficients. The processor is further operable to generate a group delay for the channel based upon the generated phase response.

The adaptive equalizer and weight update device converge the transfer function of the adaptive equalizer until the demodulated information signal generated by the adaptive equalizer fairly represents the ideal information signal. In a preferred embodiment, a symbol decision processor or device may be used to further determine the ideal information signal. The resulting coefficients correspond to the transfer function of the network components and propagation medium on the demodulated signal. When the coefficients of the adaptive equalizer are complex values having real and imaginary components, the phase angles of the response of the adaptive equalizer over the bandwidth of the signal may be computed from the discrete Fourier transform of the adaptive equalizer coefficients.

Preferably, the coefficients of the adaptive equalizer are augmented with a number of zero-valued points to make the number of values for the Fourier transform correspond to a number that is a power of two. This constraint simplifies the computational techniques for the discrete Fourier transform using known fast Fourier transform (FFT) methods. The result of the FFT of the augmented adaptive equalizer coefficients provides the frequency response of the network up to the output of the demodulated signal. The angle whose tangent is the ratio of the imaginary component of a frequency response value to its real component is representative of the phase angle associated with that frequency response value. Thus, each frequency response value corresponds to a phase angle at a particular frequency.

The array of phase angles that are derived from the FFT of the augmented adaptive equalizer coefficients may be used to compute the group delay of the channel. Group delay is defined as the ratio of the change in angle to the change in frequency. This ratio may be computed between each angle in the array derived from the FFT of the augmented adaptive equalizer coefficients. When this ratio is multiplied by the appropriate FFT scaling factor, which may suitably be the number of FFT steps per bandwidth of the channel being evaluated, the group delay is determined.

The group delay value may be displayed and/or transmitted to inform a technician or other operator of the channel group delay for diagnostic purposes without interfering with reception of any channels at a subscriber's site. Alternatively, the array of phase angles may be evaluated with a linear regression analysis or parametric function method to determine a phase angle function. The first derivative of this function is a group delay function, which is a constant in the case of a linear phase angle function.

The system incorporating the method of the present invention may be included in a network analyzer. When the analyzer is used at a distribution site or subscriber tap, it provides information regarding the phase angles of the frequency response of the channel from the head end to the site where the analyzer is coupled to the network. If a second analyzer implementing the present invention is used at another distribution site or subscriber tap, the phase measurements at the two sites may be stored and later used to determine the response of the network between the two sites. For example, a comparison of the phase angle response at the two locations may be used to determine the phase response of the network between the two network sites. Alternatively, the data may be communicated between the two analyzers over some remaining channel of the network so that the comparison of the two responses may be made while the operators are in the field, provided the two sites are coupled together by a communication channel.

One network analyzer implementing the method of the present invention may also be used for the purpose of obtaining a phase response between two network sites by storing the phase angle measurements at one site and then taking the network analyzer to a second site to make phase angle measurements at that site. The network analyzer may then compare the phase responses at the site where it is currently operating to the phase responses previously stored. By using a network analyzer made in accordance with the principles of the present invention in this manner, data may be acquired at different points in the network without requiring the head end to drive a reference signal through one or more channels of the network. Thus, the phase response of the network may be determined at various points within the network without disrupting subscriber service.

The method of the present invention determines a group delay of a channel in a CATV system. The method includes obtaining a set of equalizer coefficients from an equalizer, said set of equalizer coefficients representative of a measure of a response of the channel. The method also includes generating a phase response of the channel based upon the set of equalizer coefficients. Thereafter, the group delay for the channel is generated based upon the generated phase response.

Taking a discrete Fourier transform of the equalizer coefficients over the bandwidth of the channel being evaluated is the preferred method for determining the frequency response of the equalizer. By computing the ratio of the imaginary components to the real components for each frequency response value, the phase angles of the channel are determined over the bandwidth of the channel. The group delay for the channel may then be determined using the phase angles of each frequency response value.

The system and method of the present invention may be used to determine the phase response of a communication channel in a CATV communication network without disrupting subscriber service. This phase response may then be used to determine the group delay of the channel being evaluated. This information may be displayed for an operator at the site where a demodulated signal is being received over the channel or the data may be stored for later analysis. Alternatively, the system and method of the present invention may be implemented in a digital receiver and stored for later retrieval or it may be transmitted over a telemetry channel or the like to the head end for analysis.

These and other advantages and features of the present invention may be discerned from reviewing the accompanying drawings and the detailed description of the invention.

### BRIEF DESCRIPTION OF THE DRAWINGS

The present invention may take form in various components and arrangement of components and in various steps and arrangement of steps. The drawings are only for purposes of illustrating an exemplary embodiment and are not to be construed as limiting the invention.

FIG. 1 is a schematic of an exemplary CATV communication network in which the present invention may be used;

FIG. 2 is a graphical depiction of a digital modulation scheme that may be used in the network of FIG. 1;

FIG. 3 is a block diagram of a system that may be coupled to the network of FIG. 1 and used to implement the method of the present invention;

FIG. 4 is a flowchart of an exemplary method that may be used in the system of FIG. 3 to compute a phase response of a channel used in the network of FIG. 1;

FIG. 5 is a flowchart of an exemplary method that may be used in the system of FIG. 3 to compute a group delay of a channel used in the network of FIG. 1; and

FIG. 6 is a block diagram of an alternative system that may be coupled to the network of FIG. 1 and used to implement the method of the present invention;

### DETAILED DESCRIPTION OF THE INVENTION

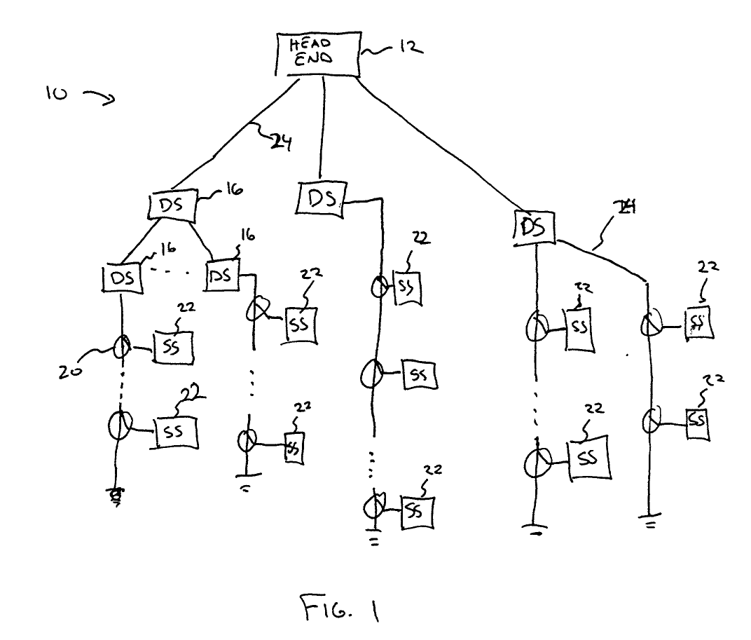

FIG. 1 depicts a schematic of a CATV communication network 10 in which the present invention may be used. Content or information signals are generated via playback machines or received via satellite and the like at the head end 12 of the network 10. The head end 12 uses these information signals to modulate carrier frequencies on various channel frequencies of the network 10. The network 10 is further comprised of distribution sites 16, subscriber taps 20, and subscriber sites 22. These sites are coupled together by a propagation medium 24 that is typically coaxial cable, fiber optic cable, or a combination of both.

The frequency spectrum of the propagation medium is divided into channels that are approximately 6 MHz wide and are centered about the frequency used to define the channel. That is, some frequency _{ch} is the center frequency of the channel and frequencies approximately 3 MHz above and below that frequency are deemed to be within the channel. In general, a carrier wave at the channel frequency is modulated with an information signal to provide content for the channel.

The modulated carrier waves for all of the channels on which the network 10 provides content are transmitted via a transmitter at the head end 12 to a plurality of distribution sites 16. The signals are amplified for further transmission at distribution sites 16. From a distribution site 16, the signals may be delivered over the propagation medium 24 to other distribution sites 16 or to a plurality of subscriber sites 22 via subscriber taps 20. The subscriber taps 20 provide the frequency spectrum of propagation medium 24 to a subscriber site 22 with little attenuation of the signals being transmitted in the bandwidth of medium 24. That is, taps 20 are designed to provided the signals on medium 24 to a subscriber site 22 without causing significant parasitic loss of signals on medium 24. The signals are decoded at the subscriber site and used to drive televisions, computers, or the like.

A common modulation scheme used in known CATV systems is the QAM modulation scheme. Pixel data of images, such as the pixels of a frame of moving picture data, to be transmitted over a CATV system are encoded by a known method, such as one of the Moving Picture Expert Group (MPEG) methods. Once the image data is encoded using an MPEG scheme or the like, this encoded data stream is used to modulate a carrier frequency for a channel in accordance with a known digital modulation scheme, such as QAM. The encoded data stream is used to modulate the amplitude and phase of the carrier frequency to incorporate one of a predetermined number of pulses on the carrier wave.

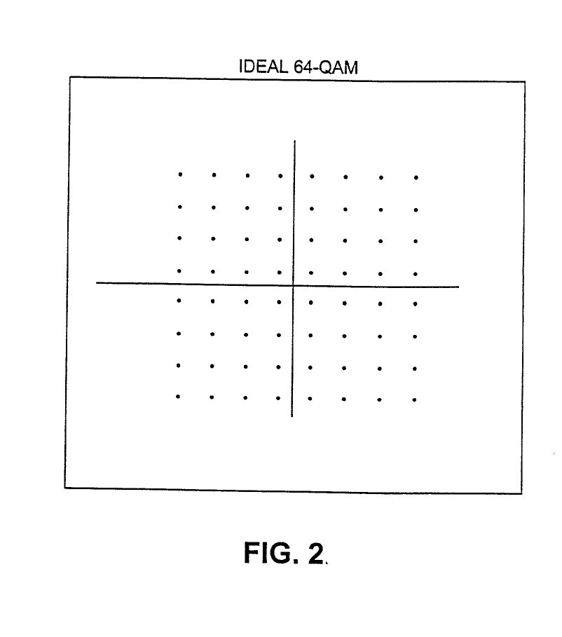

In one commonly used digital modulation scheme, known as the QAM-64 scheme, there are 64 possible pulses that may be imposed onto the carrier wave. Each of these pulses may be perceived as corresponding to a point on a graphical representation. FIG. 2 shows such a graphical representation of the QAM-64 scheme. As shown in FIG. 2, the 64 points of the representation are centered about zero. The horizontal and vertical axes of the graph represent the orthogonal components of a modulation signal represented by a point. Thus, each signal may be described as a (x,y) point or as a phasor having a magnitude and angle.

The graphical representation shown in FIG. 2 is the signal constellation for the QAM-64 signal. Signal distortions caused by a transmitter, propagation medium, or the demodulation components of a receiver may shift, attenuate, or amplify a modulation signal so that a received pulse does not correspond exactly to one of the discrete points on a signal constellation for a modulation scheme. When the received pulses stray too far from their original constellation points, reception errors may occur. As a consequence, it is desirable to perform maintenance or repair of the network 10 to locate the source of deteriorating performance before it disrupts service.

FIG. 3 is a block diagram of an exemplary system that may be coupled to the network of FIG. 1 to implement the phase analysis method of the present invention. The system includes a receiver 40 and a phase response processor 64. In the example discussed herein, the receiver 40 includes an adaptive equalizer 44, a symbol decision processor 48, and a weight adjuster 50. It will be appreciated that the receiver 40 may suitably include other elements not related to the present invention.

The components of a receiver 40 operate on an information signal recovered by demodulating the modulated carrier wave for a select channel. To this end, the receiver 40 will preferably include, or be connected to, a tuner 54 and a demodulator 56. The tuner 54, which includes frequency conversion equipment and is well known in the art, tunes to a particular channel or frequency band that is being measured. The demodulator 56 then obtains the information signal 42, which is distorted or corrupted by the transmission equipment. Suitable digital demodulation equipment is well known.

The demodulated information signal 42 is provided to the adaptive equalizer 44 and the output of the adaptive equalizer 44 is provided to the symbol decision processor (SDP) 48.

The transfer function of the adaptive equalizer 44 compensates for the distortion of the demodulated information signal caused by the transfer function of the propagation medium and any network components that have operated on the signal after its use to modulate the carrier frequency for a channel at the head end 12. To this end, the tap coefficients of the adaptive equalizer 44 are adapted to compensate the signal input to the adaptive equalizer 44 responsive an error signal generated by the SDP 48.

To generate the error signal, the SDP 48 receives a signal pulse from the adaptive equalizer 44 and determines which point in a constellation map best correlates to the pulse. Thus, the SDP 48 determines what the pulse would have been if the signal had been transmitted and delivered to the SDP 48 without any distortion. The difference between the point identified by the actual signal and the point determined to be the correct point by the SDP 48 defines the error signal. Typically, this error signal has a component along both axes and, accordingly, the coefficients of adaptive equalizer 44 are complex. The SDP 48 provides the error signal to the weight adjuster 50. The weight adjuster 50 uses the error signal to adjust the weights or coefficients of the transfer function implemented by adaptive equalizer 44 to minimize the error signal.

As discussed above, the SDP 48 determines what each received pulse of the information signal would have been without distortion. From this determination, the SDP 48 generates a reconstructed information signal. The reconstructed information signal is ideally the same as the information signal that was used to modulate the carrier frequency of the channel at head end 12. Ideally, the error signal generated by the SDP 48 constitutes the difference between the output of the adaptive equalizer 44 and the reconstructed information signal. The reconstructed information signal may be further be used to obtain the information signal content, if necessary for another function of the receiver 40 that is outside the scope of the invention.

In the process of minimizing the error signal, the weight adjuster 60 converges the output of adaptive equalizer 44 to the ideal demodulated information signal. As a consequence, the transfer function of the adaptive equalizer 44 represents the inverse of the transfer function of the channel and network components that delivered the signal to the adaptive equalizer 44.

The coefficients of the transfer function of the adaptive equalizer 44 may be used by the phase response processor (PRP) 64 to generate the frequency response of the channel and the network components that delivered the demodulated information signal to the adaptive equalizer 44. Preferably, the weight adjuster 50 maintains the first coefficient of the adaptive equalizer 44, sometimes denoted as h₀, as the unity factor or 1+0j in complex notation. The frequency response may then be used to compute the phase angles of the frequency response as discussed below.

The PRP 64 may be a microprocessor or controller having memory and components for display output generated by the PRP 64 to a user. For example, PRP 64 may be a Motorola 68331 with 1 MB of RAM. The processor is preferably coupled to an LCD or other display so a user may view the data generated by the PRP 64. The microprocessor or controller may be coupled to the ASIC that implements the adaptive equalizer 44, such as a BCM3125 manufactured by Broadcom of Irvine, Calif., by a serial/peripheral interface (SPI) so that the coefficients of the adaptive equalizer 44 may be supplied to PRP 64. The adaptive equalizer 44 is often integrally formed with the demodulator 56 in many commercial devices, including the one described above.

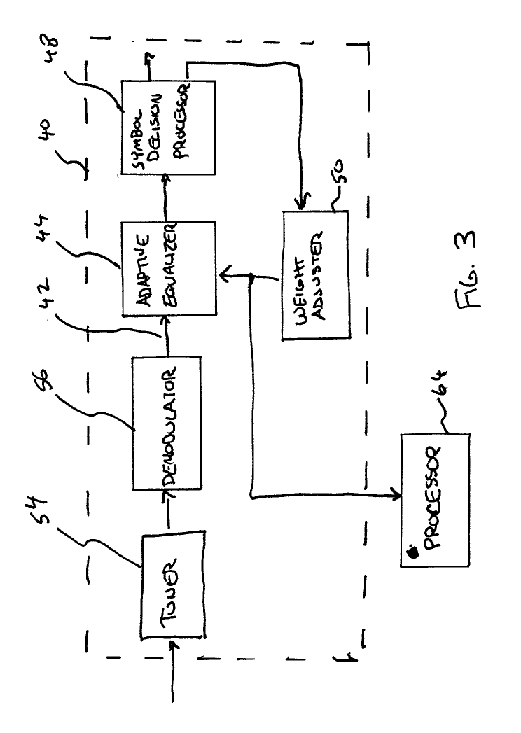

A flowchart of an exemplary process for determining the phase response of the channel is shown in FIG. 4. The process for generating a phase response, which may be implemented in software executed by the microprocessor of PRP 64, reads the adaptive equalizer coefficients from the coefficient adjuster 50 (step 100). These coefficients are preferably augmented with a sufficient number of zero coefficients to preferably provide 256 values (step 104). The augmentation facilitates a fast Fourier transform of the values.

The values in the array are then used to perform a discrete Fourier transform, preferably using fast Fourier transform (FFT) techniques, so that a frequency response for the transfer function is obtained (step 108). The frequency response represents the frequency response of the adaptive equalizer. The transformed values of the frequency response are then used to obtain the phase angles for each frequency increment over the bandwidth of the channel (step 112). Preferably, the increments over the bandwidth of the channel are 1/256^{th} of the channel bandwidth. The phase angles are preferably obtained by determining the angle whose tangent function is defined by the ratio of the imaginary portion of a frequency response value to its real portion. A plot of these phase angles at the frequency increments may be determined and displayed by the PRP 64.

It is noted, however, that the phase response must be inverted to obtain the phase response of the system. Accordingly, to display the phase response of the system, the PRP 64 would typically change the sign of the calculated phase angles prior to display. Although the phase response of a channel over its bandwidth is an important parameter for CATV networks and the above described method of its determination and display for CATV diagnosis is previously unknown, it is further preferable to determine the group delay parameter for a channel.

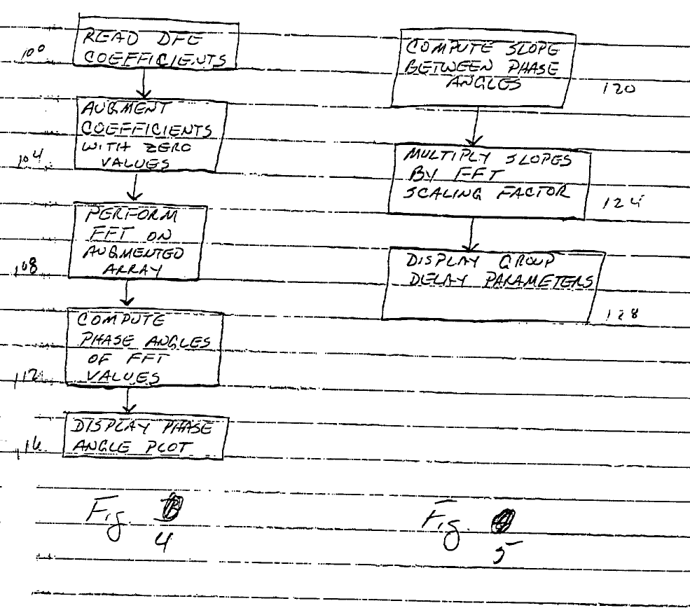

Group delay is defined as the ratio of the change in phase angle to the change in frequency. An exemplary method for computing group delay from the array of phase angles is shown in FIG. 5. The change in phase angle between two points may be computed as the difference in phase angle for the points (step 120). This difference is then multiplied by the FFT scaling factor (step 124), if the phase angles were obtained from an FFT of discrete data. The resulting product provides the group delay. However, if the phase angles had not yet been inverted, then the group delay is the group delay of the equalizer 44, and thus the inverse of the group delay of the elements in the network that delivered the signals to the equalizer 44. Accordingly, in such a case it is necessary to invert the group delay to obtain the system group delay. The group delay may then be displayed (step 128).

If the difference in phase angle between each frequency increment in the array is computed and multiplied by the FFT scaling factor, then the group delay may be displayed as the plot of a function. The FFT scaling factor is the number of summation steps required for computation of the FFT over the bandwidth of the channel. Alternatively, the group delay may be computed by first plotting the phase angles and fitting a parametric function to the points. For example, linear regression analysis may be used to fit a line to the phase angles and the slope of the line is the group delay of the channel. If the parametric equation that best fits the phase angles is non-linear then the group delay may be computed as the first derivative of the parametric function. A plot of the derivative of the phase angle function may then be displayed as the group delay of the channel over its bandwidth.

In implementing the present invention, the PRP 64 and software for the phase angle response computations may be part of a network analyzer. Typically, network analyzers are computer systems with a display that are housed within a unit capable of transportation to various sites. Network analyzers typically include receiver circuitry, including frequency conversion and demodulation equipment. A technician or other operator would take a network analyzer implementing the present invention to a distribution site 16 or subscriber site 22 and couple the analyzer to the network at the site. PRP 64 then obtains coefficients from adaptive equalizer 44 while it is operating without disrupting service to any sites downstream.

Operating on these coefficients as described above, the phase response and/or the group delay of a channel may be determined and displayed to an operator for diagnostic purposes. The phase data at a site may then be stored in the memory of the analyzer. An operator may then de-couple the analyzer from the site and take it to another distribution site 16 or subscriber site 22 for coupling to the network. At the second site, the phase response of the same channel analyzed at the first site may be obtained. The phase response of the channel at the two sites may then be compared to determine the phase response to the network medium and components between the two sites.

Alternatively, two different analyzers implementing the present invention may be used at each site. The phase response determined at a site may then be transmitted via a telemetry channel to head end 12 for comparison or to an analyzer at another site provided the network analyzers are provided with a transmitter/receiver for upconverting/downconverting data to be transmitted on a telemetry channel. In another implementation of the present invention, a receiver may implement the functionality of the PRP 64 to perform self-diagnosis or for transmission of phase response data to head end 12. In any of these implementations or their equivalents, a phase response of a channel may be obtained to provide information about a network. In particular, the group delay of a channel may be determined.

While the present invention has been illustrated by the description of exemplary processes, and while the various processes have been described in considerable detail, it is not the intention of the applicant to restrict or in any limit the scope of the appended claims to such detail. Additional advantages and modifications will also readily appear to those skilled in the art. The invention in its broadest aspects is therefore not limited to the specific details, implementations, or illustrative examples shown and described. Accordingly, departures may be made from such details without departing from the spirit or scope of applicant's general inventive concept.

What is claimed is:

1. An arrangement for generating the group delay of a communication system, the arrangement comprising:
an adaptive equalizer operably coupled to receive a demodulated digital signal, the adaptive equalizer operable to generate an equalized signal using a set of equalizer coefficients;
a weight update device operable to generate the set of equalizer coefficients using an error signal, the error signal representative of a difference between an ideal demodulated signal and the received demodulated signal;
a processor operably coupled to receive said set of equalizer coefficients from the weight update device, the processor operable to
generate a phase response of the channel based upon the set of equalizer coefficients;
generate a group delay for the channel based upon the generated phase response.

2. The arrangement of claim I wherein said processor is operable to perform a discrete Fourier transform to generate the phase response.

3. The arrangement of claim 2 wherein said processor is operable to perform the discrete Fourier transform by performing a fast Fourier transform.

4. The arrangement of claim 3 wherein said processor is further operable to augment the equalizer coefficients with a number of zero coefficients sufficient to produce a number of coefficients that is a power of two prior to performing the fast Fourier transform.

5. The arrangement of claim 1 wherein the processor is operable to generate the group delay by determining the slope between the phase angles in order to determine an equalizer group delay.

6. The arrangement of claim 5 wherein the processor is operable to generate the group delay by inverting the equalizer group delay to obtain a system group delay.

7. The arrangement of claim 5 wherein the processor is operable to determine the slope by:
fitting a function to the phase angles; and
computing a first derivative of the function.

8. The arrangement of claim 5 wherein the processor is operable to determine the slope by:
computing a difference between two phase angles; and
computing a difference between the frequencies corresponding to the two phase angles to generate a group delay measurement for the channel.

9. The arrangement of claim 1 further comprising a symbol decision device coupled to the adaptive equalizer to receive the equalized signal and generate the error signal based on the equalized signal.

10. A method for determining phase response of a channel in a CATV system comprising:
a) obtaining a set of equalizer coefficients from an equalizer, said set of equalizer coefficients representative of a measure of a response of the channel;
b) generating a phase response of the channel based upon the set of equalizer coefficients;
c) generating a group delay for the channel based upon the generated phase response.

11. The method of claim 10 wherein step b) further comprises computing a discrete Fourier transform of the set of equalizer coefficients to determine components for computing the phase angles.

12. The method of claim 10 wherein step b) further comprises performing a fast Fourier transform of the set of equalizer coefficients to determine components for computing the phase angles.

13. The method of claim 11 wherein step b) further comprises augmenting the set of equalizer coefficients, prior to performing the fast Fourier transform, with a sufficient number of zero coefficients to make the set of equalizer coefficients a power of two.

14. The method of claim 13 wherein step b) further comprises determining a plurality of phase angles from the computed discrete Fourier transform, the plurality of phase angles constituting the phase response.

15. The method of claim 1 1 wherein step b) further comprises determining a plurality of phase angles from the computed discrete Fourier transform, the plurality of phase angles constituting the phase response.

16. The method of claim 10, wherein step c) further comprises determining a slope between at least two of the phase angles.

17. Th method of claim 16 wherein step c) further comprises multiplying the slope by a scaling factor to generate an equalizer group delay.

18. The method of claim 17 wherein step c) further comprises inverting the equalizer group delay to obtain the group delay for the channel.

19. The method of claim 16 wherein the slope determination further comprises:
fitting a function to the phase angles; and
computing a first derivative of the function.

20. The method of claim 19, wherein the function fitting comprises using one of a linear regression method and a parametric function method to fit a function to the phase angles.

21. The method of claim 16 wherein the slope determination comprises:
computing a difference between two phase angles; and
computing a difference between the frequencies corresponding to the two phase angles to generate a group delay measurement for the channel.

22. A method for determining phase response of a channel in a CATV system comprising:
a) obtaining a set of equalizer coefficients from an equalizer, said set of equalizer coefficients representative of a measure of a response of the channel;
b) generating a phase response of the channel based upon the set of equalizer coefficients;
c) determining a slope between at least two of the phase angles;
d) multiplying the slope by a scaling factor to generate an equalizer group delay; and
e) inverting the equalizer group delay to obtain the group delay for the channel.
